(19) United States
(12) Patent Application Publication
(10) Pub. No.: US 2026/0091408 A1
(43) Pub. Date: Apr. 2, 2026

(54) ULTRASOUND TRANSDUCER

(71) Applicant: Method AI, Inc., Cleveland, OH (US)

(72) Inventors: Jeremy Brown, Halifax (CA); Charles D. Emery, Gilbert, AZ (US); Andrea Felling, Halifax (CA); Jonathan Fincke, Belmont, MA (US); Katherine Latham, Dartmouth (CA); David P. Nelson, Snohomish, WA (US)

(73) Assignee: Method AI, Inc., Cleveland, OH (US)

(21) Appl. No.: 18/904,915

(22) Filed: Oct. 2, 2024

(51) Int. Cl. B06B 1/02; H01L 25/07; H01L 29/84

(52) U.S. Cl. CPC B06B 1/0207; H10W 90/00; B06B 2201/50; H10D 48/50

(57) ABSTRACT

An ultrasound transducer may include a printed circuit board (PCB) and a transducer array. The transducer array may include a, an array of Piezo resistive elements supported by the substrate, at least one connector footing supported by the substrate, electrically conductive lines connected to the piezoresistive elements, and an array of connectors electrically connected to the printed circuit board and to the electrically conductive lines. The at least one connector footing supports the array of connectors.

### BACKGROUND

Ultrasound transducers are used to create high-frequency sound waves. Reflections or echoes of such sound waves may be used to detect objects or measure distances. In medicine, ultrasound transducers are sometimes used to generate images of organs, tissues or other structures inside a body.

### BRIEF DESCRIPTION OF THE DRAWINGS

FIG. 1 is a schematic diagram illustrating portions of an example ultrasound transducer.

FIG. 2 is a top view schematically illustrating portions of an example ultrasound transducer.

FIG. 3 is a sectional view of the ultrasound transducer of FIG. 2 taken along line 3-3.

FIG. 4 is a sectional view of the ultrasound transducer of FIG. 2 taken along line 4-4.

FIG. 5 is a top view schematically illustrating portions of an example ultrasound transducer.

FIG. 6 is a sectional view of the ultrasound transducer of FIG. 5 taken along line 6-6.

FIG. 7 is a sectional view of the ultrasound transducer of FIG. 5 taken along line 7-7.

FIG. 8 is a top view schematically illustrating portions of an example ultrasound transducer.

FIG. 9 is a sectional view of the ultrasound transducer FIG. 8 taken along line 9-9.

FIG. 10 is a sectional view of the ultrasound transducer of FIG. 8 taken along line 10-10.

FIG. 11 is a sectional view of the ultrasound transducer of FIG. 8 taken along line 11-11.

FIG. 12 is a sectional view of the ultrasound transducer of FIG. 8 taken along line 12-12.

FIG. 13 is a flow diagram of an example method for forming an ultrasound transducer.

FIG. 14A is a top view of a diced plate forming Piezo resistive elements of an ultrasound transducer.

FIG. 14B is a perspective view of the diced plate of FIG. 14A.

FIG. 15 is a perspective view of the diced plate with filled kerfs.

FIG. 16 is a top view illustrating trimming of the diced plate of FIG. 15.

FIG. 17 is a top perspective view illustrating the trimmed plate of FIG. 16.

FIG. 18 is a top perspective view illustrating the addition of a connector footing about the trimmed plate of FIG. 17.

FIG. 19 is a top perspective view illustrating application of electrically conductive layers to a top and a bottom of the plate of FIG. 18.

FIG. 20 is a top perspective view illustrating patterning of electrically conductive lines and connectors on the plate of FIG. 18.

FIG. 21 is a bottom perspective view illustrating patterning of electrically conductive layers and connectors on the plate of FIG. 18.

FIG. 22 is a top perspective view illustrating electrical connection of the connectors of FIG. 20 to a printed circuit board.

FIG. 23 is a bottom perspective view illustrating electrical connection of the connectors of FIG. 21 to the printed circuit board.

FIG. 24 is a top perspective view illustrating the addition of connector footings along a top face of the plate of FIG. 17.

FIG. 25 is a bottom perspective view illustrating the addition of connector footings along a bottom face of the plate of FIG. 17.

FIG. 26 is a top perspective view illustrating the provision of electrically conductive lines and connectors on the top face of the plate of FIG. 24 and the electrical connection of the connectors to a printed circuit board.

FIG. 27 is an enlarged view of a portion of the ultrasound transducer of FIG. 26.

FIG. 28 is a bottom perspective view illustrating the provision of electrically conductive lines and connectors on the bottom face of the plate of FIG. 24 and the electrical connection of the connectors to the printed circuit board.

FIG. 29 is a bottom perspective view illustrating portions of an example ultrasound transducer.

FIG. 30 is a bottom perspective view of the ultrasound transducer of FIG. 29.

FIG. 31 is a top perspective view illustrating portions of an example ultrasound transducer.

FIG. 32 is a bottom perspective view of the ultrasound transducer of FIG. 31.

Throughout the drawings, identical reference numbers designate similar, but not necessarily identical, elements. The figures are not necessarily to scale, and the size of some parts may be exaggerated to more clearly illustrate the example shown. Moreover, the drawings provide examples and/or implementations consistent with the description; however, the description is not limited to the examples and/or implementations provided in the drawings.

### DETAILED DESCRIPTION OF EXAMPLES

Disclosed are example ultrasound transducers and methods for forming ultrasound transducers. The example ultrasound transducers and methods facilitate the fabrication of smaller, more robust and potentially less expensive ultrasound transducers. The example ultrasound transducers and methods utilize at least one connector footing which supports the connectors or the locations at which a transducer array is electrically connected to a printed circuit board.

The transducer array may comprise an array of Piezo resistive elements formed on or in a substrate. The substrate may further provide connectors or connecting locations at which the Piezo resistive elements are electrically connected to the printed circuit board. The connectors or connecting locations may undergo high levels of mechanical force and/or heat as electrically conductive wires or traces are bonded or otherwise connected to the transducer array at the connection locations. As the size of the transducer array becomes smaller or the density of the Piezo resistive elements increases, the risk that those mechanical forces and/or heat experienced by the transducer array during connection processes or bonding procedures may damage the transducer array also increases.

The connector footing is supported by the substrate. The connector footing is more robust against mechanical force and/or heat as compared to the material or composite of multiple materials from which the substrate is formed. As result, the connector footing reduces the likelihood of damage to the transducer array during bonding or other connection of the transducer array to the printed circuit board at the connection locations. Such connector footings may facilitate the use of smaller or thinner transducer arrays or the substrates that provide the array of Piezo resistive elements. Such connector footings may facilitate a higher density of Piezo resistive elements for enhanced transducer performance.

The at least one connector footing is supported by the substrate that provides the array of Piezo resistive elements. In some implementations, the at least one connector footing comprises at least one layer of a more robust material or materials positioned on top of (or on bottom of) the substrate. In some implementations, the at least one connector footing comprises at least one layer of a more robust material or materials deposited or otherwise formed in a channel or groove in the substrate. In some implementations, the at least one connector footing comprises at least one layer of a more robust material or materials which are bonded or otherwise joined to the substrate along a peripheral edge of the substrate. In some implementations, the least one connector footing has a top face that is not covered by the substrate proximate a top face of the substrate and has a bottom face that is not covered by the substrate proximate a bottom face of the substrate.

In some implementations, the top face of the connector footing may be flush, projecting above or recessed below a top face of the substrate. In some implementations, the bottom face of the connector footing may be flush, projecting above or recessed below a bottom face of the substrate. In some implementations, the top face of the connector footing and/or the bottom face of the connector footing may underlie additional layers or coatings deposited or otherwise formed upon the top face and/or the bottom face, between such faces and the locations at which the electrically conductive lines or traces are bonded or connected.

In some implementations, the at least one connector footing comprises a first footing along a first face of the substrate for supporting a first set of connectors for the Piezo resistive elements and a second connector footing along a second opposite face of the substrate for supporting a second set of connectors for the Piezo resistive elements. In some implementations, the first footing and the second footing are on opposite sides of the substrate, along opposite peripheral edges of the substrate, or on top of or in channels proximate to opposite side edges of the substrate. In some implementations the first connector footing, and the second connector footing are supported by the substrate non-parallel to one another. For example, in some implementations, the first connector footing, and the second connector footing may extend orthogonal to one another, along opposite orthogonal edges of the substrate, or on top of or in channels proximate to orthogonal edges of the substrate.

In some implementations, the at least one connector footing may comprise a set of connector footings that surround the substrate and/or that surround the array of Piezo resistive elements. For example, the at least one connector footing may comprise a first pair of connector footings that extend along opposite sides of the substrate and that support connectors or connector locations on a first face of the substrate, and a second pair of connector footings that extend along opposite sides of the substrate, orthogonal to the first pair of connector footings, and that support connectors or connector locations on a second opposite face of the substrate. In some implementations, the first pair of connector footings may be provided or formed in a first channel along the first face of the substrate while the second pair of connector footings may be provided or formed in a second channel along the second face of the substrate. In some implementations, the first pair of connector footings and the second pair of connector footings may be integrally formed as a single unitary body about the substrate or about the array of Piezo resistive elements, wherein the first and second pair of connector footings form a continuous, uninterrupted frame that has a top face along a top face of the substrate or a top face of the array of Piezo resistive elements, and a bottom face along a bottom face of the substrate or a bottom face of the array of Piezo resistive elements.

In some implementations, a panel or plate of Piezo resistive material may comprise a series of grooves or channels (kerfs) formed between and separating the individual Piezo resistive elements which are in the form of pillars. The kerfs may be filled with a different material, such as an epoxy. In some implementations, the material forming the connector footing is different than the material filling the kerfs.

In some implementations, the kerfs extend completely to the edges of the panel or plate, wherein the connector footing is mounted, bonded, joined or otherwise formed adjacent to and along the outer edges of the diced panel or plate. In such implementations, the material of the connector footing may be the same material as that forming the panel or plate prior to dicing and kerf filling or may be formed from a different material distinct from both the kerf filling material and the material forming the panel or plate prior to dicing.

In some implementations in which the kerfs extend completely to the edges of the panel or plate, an additional groove may be formed in the diced and curve filled portion of the panel or plate, inside of the outer edges of the diced and kerf filled portion of the panel or plate. In such implementations, the additional groove may be filled with a material of the connector footing which may be the same material as that forming the panel or plate prior to dicing and kerf filling or may be formed from a different material distinct from both the kerf filling material and the material forming the panel or plate prior to dicing. The material filling the additional groove is different from the material filling the kerfs.

In some implementations, the kerfs may terminate prior to reaching edges of the panel are plate, wherein the diced and kerf filled portion of the panel or plate is bordered by an undiced, solid, or monolithic portion of the panel or plate. Lacking any dicing and lacking any kerf filling material, this undiced border edge portion of the panel or plate may provide a more robust footing for a subsequently formed connector array. In such an implementation, the fund diced border edge portion of the panel or plate, forming the connector array, may be formed from the same Piezo resistive material that forms the pillars of the Piezo resistive elements.

Disclosed is an example ultrasound transducer that may include a printed circuit board (PCB) and a transducer array. The transducer array may comprise a substrate, an array of Piezo resistive elements supported by the substrate, at least one connector footing supported by the substrate, electrically conductive lines connected to the piezoresistive elements and an array of connectors electrically connected to the printed circuit board and to the electrically conductive lines. The at least one connector footing supports the array of connectors.

Disclosed is an example method for forming an ultrasound transducer. The method may comprise forming an array of Piezo resistive elements on a substrate, forming at least one connector footing on the substrate, forming an array of connectors on the at least one connector footing, electrically connecting the array of Piezo resistive elements to the array of connectors, and electrically connecting the array of connectors to a printed circuit board.

In one example implementation, the array of Piezo resistive elements are formed on the substrate by dicing a composite pattern in a Piezo resistive substrate, such as a PZT or PMM-PT plate. Such dicing may be formed using a dicing saw or laser. The composite pattern may be cut to full-length on a first pass it is fully supported or may be diced halfway, partially filled and flipped over and repeated. In some implementations, the gaps or channels (kerfs) between the individual Piezo resistive elements may be filled with a material such as an unfilled epoxy or urethane. Metal oxides, micro balloons and other powders may sometimes be added to function as scatterers to help reduce inter-element cross talk. Such glass micro balloons are described powders that may also reduce shrinkage and thermal expansion.

In some implementations, the substrate provided with the composite pattern, the array of “pillars” and filled intervening kerfs, may be trimmed out to a final shape. In some implementations, the substrate is cut or trimmed at an angle non-parallel or oblique to the original composite pattern formed by the original dicing. For example, in some implementations, the substrate may be cut at a 45-degree angle to the orthogonal or perpendicular kerfs formed by the initial dicing. Such an oblique shaping may facilitate breaking up any diced pattern symmetry (row to row performance variability) and may reduce lateral modes.

In one implementation, the at least one connector footing is formed by cutting or otherwise forming a channel or groove in the substrate and subsequently filling the channel or groove with a more robust material, material that is different than the material that forms the substrate. In one implementation, the at least one connector footing is formed by molding, bonding or otherwise securing a layer or bar of the material that forms the connector footing to a peripheral edge of the substrate. As indicated above, in some implementations, the connector footing may be configured to support connectors or connection locations on opposite faces, adjacent to or along opposite faces of the substrate and the array of Piezo resistive elements. As indicated above, in some implementations, the connector footing may comprise multiple footings that extend along opposite and/or orthogonal edges of the substrate. In some implementations, the connector footing may comprise a continuous footing that surrounds the substrate and/or Piezo resistive elements.

In some implementations, the array of connectors and the electrical connection of the connectors to the array of Piezo resistive elements are formed by forming an electrically conductive layer over the array of Piezo resistive elements and over the connector footing, wherein the layer is patterned to form the connectors that overlie the connector footing and to form electrically conductive traces that are electrically connected to the Piezo resistive elements. In some implementations, such patterning may be formed with a laser. In some implementations, the connectors or connection locations may be formed on the connector footings independent of the formation of electrically conductive lines or traces that connect the connectors or connection locations to the individual Piezo resistive elements.

In some implementations, the connectors or connection locations are formed in an array along an edge or edges of the substrate. The array of connectors may then be joined to the printed circuit board. For example, in some implementations, the array of connectors are electrically connected to corresponding connectors of the printed circuit board by wire bonding.

In some implementations, the electrical connections to the individual Piezo resistive elements extend from opposite sides of the substrate in a staggered fashion. For example, connectors on one side of the substrate may be connected to rows 1, 3, 5 . . . (the odd rows) of Piezo resistive elements while connectors on the opposite side of the substrate may be connected to rows 2, 4, 6 . . . (the even rows) of the Piezo resistive elements. Such staggering may provide for a greater density of Piezo resistive elements for the ultrasound transducer.

In some implementations, the substrate and/or the array of Piezo resistive elements are formed from a ceramic material, such as a PZT or PMN-PT material. In such implementations, the at least one connector footing is formed from a more robust material. For example, the connector footing may comprise or may be formed from a dielectric material having an electrical conductivity having an electrical conductivity sufficiently small to avoid electrical cross-talk between neighboring electrical contacts, connectors or lines and a Young's Modulus stiffness of at least 20 GPa. In some implementations, the connector footing may additionally have a low coefficient of thermal expansion (CTE) to reduce alignment error and delamination stresses during fabrication when subjected to temperature excursions.

In some implementations, the connector footing may be formed from an electrical insulator such as boron nitride which has a Young's Modulus stiffness of 100 GPa and a thermal conductivity (k) of 750 (W/m-k). In some implementations, the connector footing may be formed from other electrically insulating material such as borosilicate glass (80 to 100 GPa), FR-4 (10-25 GPa), alumina nitride (270-350 GPa), alumina (400 GPa). Where the conductor footing is formed from PZT the thermal conductivity (k) would be between 1 and 3 W/m-k. Where the conductor footing is FR-4 the thermal conductivity would be less than 1 W/m-k.

In some implementations, connector footing may be formed from the same material as that forming the Piezo resistive elements, but wherein connector footing is solid, and is not a composite, in that it lacks the any gaps or channels (kerfs) cut into the material or filling materials within the kerfs. For example, a panel or plate of PZT/PMN-PT (55-75 GPa) may have an interior portion diced with a laser to form the Piezo resistive pillars or elements, wherein the kerfs, which are filled with an epoxy or similar material, terminate prior to reaching edges of the panel or plate and wherein the undiced edge portions of the panel or plate has a greater structural integrity and is more robust for underlying and supporting the connector array.

In implementations where a dicing saw is used to form the kerfs, the kerfs may extend completely to the edges of the PCT/PMN-PT panel such that the solid, more monolithic, un-diced connector footing is either formed along an outside of the edges of the diced PCT/PMN-PT panel or is formed by forming a groove or channel in the diced portion of the panel or plate just inside of the edges of the diced panel or plate and filling the groove or channel with the PCT/PMN-PT material or the other connector footing materials described above. In implementations where a groove or channel is formed along an inside of the edges of the diced panel or plate and wherein the groove or channel is subsequently filled with material that serves as the conductor footing, the groove or channel (and the corresponding width of the material filling the groove or channel and forming the connector footing) may have a width larger than the width of the kerfs that separate the Piezo resistive elements in the diced portion of the panel or plate. The width of the channel and the corresponding width of the conductor footing material that fills the channel is sufficiently wide to support the connector array.

For purposes of this disclosure, the term “coupled” shall mean the joining of two members directly or indirectly to one another. Such joining may be stationary in nature or movable in nature. Such joining may be achieved with the two members, or the two members and any additional intermediate members being integrally formed as a single unitary body with one another or with the two members or the two members and any additional intermediate member being attached to one another. Such joining may be permanent in nature or alternatively may be removable or releasable in nature.

For purposes of this disclosure, the phrase “configured to” denotes an actual state of configuration that fundamentally ties the stated function/use to the physical characteristics of the feature proceeding the phrase “configured to”.

FIG. 1 is a diagram schematically illustrating portions of an example ultrasound transducer 20. Ultrasound transducer 20 utilizes an example connector footing which supports connectors or connection locations at which an array of Piezo resistive elements are electrically connected to a printed circuit board. The connector footing reduces the likelihood of damage to the transducer array during bonding or other connection of the transducer array to the printed circuit board at the connection locations. The connector footing may facilitate the use of smaller or thinner transducer arrays or the substrates that provide the array of Piezo resistive elements. The connector footing may facilitate a higher density of Piezo resistive elements for enhanced transducer performance. As shown by FIG. 1, the example ultrasound transducer 20 comprises printed circuit board 24, transducer array 28, electrically conductive lines 32, and connector array 36.

Printed circuit board 24 comprises a platform that serves as an electrical interface with the transducer array 28. In some implementations, printed circuit board 24 may comprise an electrically insulative board, formed from a material such as FR4. The electrically insulative board may include electrically conductive traces which provide electrical connection to other electrical or electronic components, such as controllers and the like. Electrical control signals are transmitted to the transducer array via the printed circuit board 24. In some implementations printed circuit board 24 may surround transducer array 28. In other implementations, printed circuit board 24 may extend along a portion of the outer periphery of transducer array 28.

Transducer array 28 comprises that portion of ultrasound transducer 20 that outputs ultrasound waves and/or that detects echoes from previously emitted ultrasound waves. Transducer array 28 comprises substrate 40, Piezo resistive element array 44 and at least one connector footing 50. Substrate 40 supports Piezo resistive element array 44 and the at least one connector footing 50.

Piezo resistive element array 44 (schematically illustrated) comprises an array of Piezo resistive elements which are individually actuatable (via electrical signals) so as to stimulate the individual elements which results in the individual elements vibrating and generating ultrasound waves. In some implementations, Piezo resistive element array 44 is formed in or as part of substrate 40. For example, the layer or layers forming substrate 40 may comprise a Piezo resistive material layer that is diced to form the array of individual Piezo resistive elements. In some implementations, the Piezo resistive element array 44 is formed on top of substrate 40 or secured to a top of substrate 40. For example, the array of individual Piezo resistive elements may be patterned on top of an underlying substrate 40.

Electrically conductive lines 32 comprise electrically conductive wires or electrically conductive traces that provide electrical connections to the individual Piezo resistive elements of array 44. Electrically conductive lines 32 may comprise a signal line and a bias line (or ground line) for each of the individual Piezo resistive elements of array 44. Each individual signal line and each individual bias line may be connected to an associated individual electrical connector of array 36 for electrical connection to printed circuit board 24. As a result, each individual Piezo resistive element of array 44 may be independently and selectively actuated or electrically stimulated.

In some implementations, the signal lines and a bias lines may be provided on a single face of the array 44 of Piezo resistive elements. In some implementations, the signal lines and the bias lines may be provided on opposite faces of the array 44, respectively, making electrical contact with a top and a bottom, of each of the individual Piezo resistive elements.

In some implementations, the electrically conductive lines may be integrally formed as single unitary body with the array of connectors 36. For example, in some implementations, an electrically conductive sheet comprising one or more electrically conductive layers, may be selectively patterned to form the signal and bias lines of the electrically conductive lines 32 and the respective individual connectors of the array 36. In some implementations, a first electrically conductive sheet may be located along a first face of the array 44 and patterned to form both the signal lines of the electrically conductive lines 32 and their associated individual signal line connectors of array 36. In such an implementation, a second sheet may be located along a second opposite face of array 44 and patterned to form the bias lines of the electrically conductive lines 32 and their associated individual bias line connectors of array 36.

In some implementations, the signal and bias lines of the electrically conductive lines 32 may be formed from a single sheet or multiple sheets of electrically conductive material, wherein the sheets are patterned (through material removal techniques) to form the signal and bias lines, wherein the corresponding electrical connectors are independently or separately formed and electrically connected to the signal and bias lines. In some implementations, the electrically conductive lines 32 may each be independently formed from one another and the array of connectors 36 may each be separately and independently formed, wherein the individual electrically conductive lines 32 are electrically connected to individual connectors of the array of connectors 36.

Connector array 36 comprises an array or series of individual, electrically isolated, electrical connectors formed upon or otherwise supported by the at least one connector footing 50. The individual electrically isolated electrical connectors are individually connected to an associated signal line or an associated bias line of the electrically conductive lines 32. The individual electrically isolated electrical connectors of array 36 are further electrically connected to printed circuit board 24. In the example illustrated, each of the individual connectors of array 36 comprises an electrical contact pad to which electrically conductive lines 52 are connected. The electrically conductive lines 52 may be connected to the connectors array 36 by wire bonding, thin bonding, or the like). The electrically conductive lines 52 are further connected to printed circuit board 24. In other implementations, the individual connectors of array 36 may comprise other forms of electrical connectors for serving as an electrical connection between print circuit board 24 and the Piezo resistive element array 44.

The at least one connector footing 50 underlies and supports connector array 36. The at least one connector footing 50 is formed from a material (including a single material or multiple materials) different from the material (a single material or multiple materials) forming substrate 40 and/or has a structural makeup (solid, lacking dicing) different than that of the remaining portions of array 28. The material or structural makeup forming the at least one connector footing 50 is more robust than the material or diced structure forming substrate 40 as against the mechanical forces and/or heat that the connector array 36 may experience when being connected to electrically conductive lines 32 and/or electrically conductive lines 52. In some implementations, the substrate is formed from a ceramic material. In some implementations, the substrate is formed from a Piezo resistive material. In such implementations, the at least one connector footing 50 is formed a dielectric material having an electrical conductivity having an electrical conductivity sufficiently small to avoid electrical cross-talk between neighboring contacts, electrical connectors, or lines and a Young's Modulus stiffness of at least 20 GPa. In some implementations, the connector footing 50 may additionally have a low coefficient of thermal expansion (CTE) to reduce alignment error and delamination stresses during fabrication when subjected to temperature excursions.

In some implementations, the connector footing 50 may be formed from an electrical insulator such as boron nitride which has a Young's Modulus stiffness of 100 GPa and a thermal conductivity of 750 (W/m-k) (Watts per meter Kelvin). In some implementations, the connector footing 50 may be formed from other electrically insulating material such as borosilicate glass (80 to 100 GPa), FR-4 (10-25 GPa), alumina nitride (270-350 GPa), alumina (400 GPa).

In some implementations, connector footing 150 may be formed from the same material as that forming the Piezo resistive elements, but wherein connector footing 50 is solid, and is not a composite, in that it lacks the any gaps or channels (kerfs) cut into the material or filling materials within the kerfs. For example, a panel or plate of PZT/PMN-PT (55-75 GPa) may have an interior portion diced with a laser to form the Piezo resistive pillars or elements, wherein the kerfs, which are filled with an epoxy or similar material, terminate prior to reaching edges of the panel or plate and wherein the undiced edge portions of the panel or plate has a greater structural integrity and is more robust for underlying and supporting the connector array 36.

In implementations where a dicing saw is used to form the kerfs, the kerfs may extend completely to the edges of the PCT/PMN-PT panel such that the solid, more monolithic, un-diced connector footing 50 is either formed along an outside of the edges of the diced PCT/PMN-PT panel or is formed by forming a groove or channel in the diced portion of the panel or plate just inside of the edges of the diced panel or plate and filling the groove or channel with the PCT/PMN-PT material or the other connector footing materials described above. In implementations where a groove or channel is formed along an inside of the edges of the diced panel or plate and wherein the groove or channel is subsequently filled with material that serves as the conductor footing, the groove or channel (and the corresponding width of the material filling the groove or channel and forming the connector footing) may have a width larger than the width of the kerfs that separate the Piezo resistive elements in the diced portion of the panel or plate. The width of the channel and the corresponding width of the conductor footing material that fills the channel is sufficiently wide to support the connector array 36.

In some implementations, as indicated by broken lines, the at least one connector footing 50 is formed by cutting or otherwise forming a channel or groove in the substrate 40 and subsequently filling the channel or groove with a more robust material, material that is different than the material that forms the substrate. In one implementation, the at least one connector footing 50 is formed by molding, bonding or otherwise securing a layer or bar of the material that forms the connector footing to a peripheral edge of the substrate 40. As indicated above, in some implementations, the connector footing 50 may be configured to support connectors or connection locations on opposite faces, adjacent to or along opposite faces of the substrate 40 and the array 44 of Piezo resistive elements. As indicated above, in some implementations, the connector footing 50 may comprise multiple footings 50 that extend along opposite and/or orthogonal edges of the substrate. In some implementations, the connector footing 50 may comprise a continuous footing 50 that surrounds the substrate 40 and/or the array 44 of Piezo resistive elements.

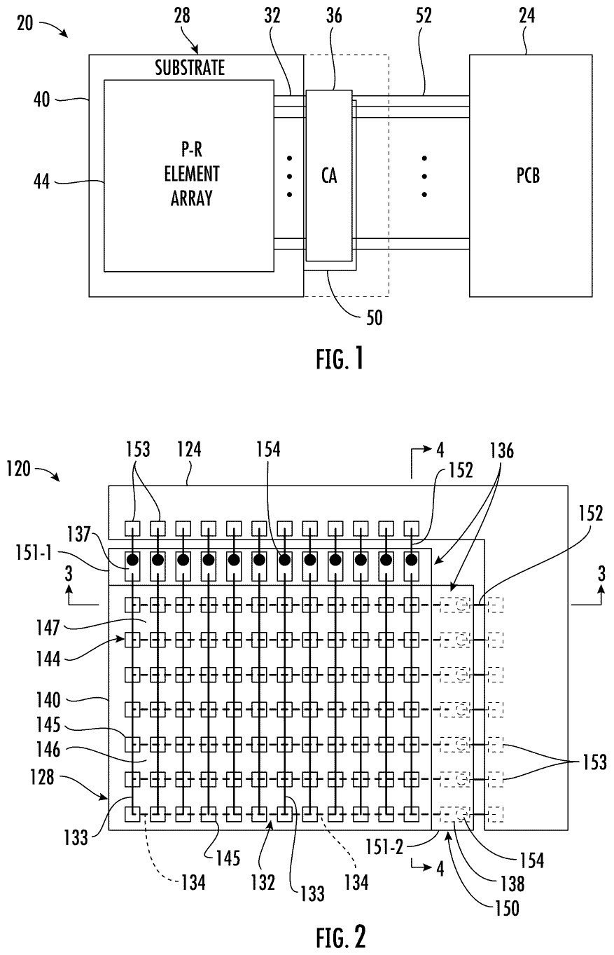

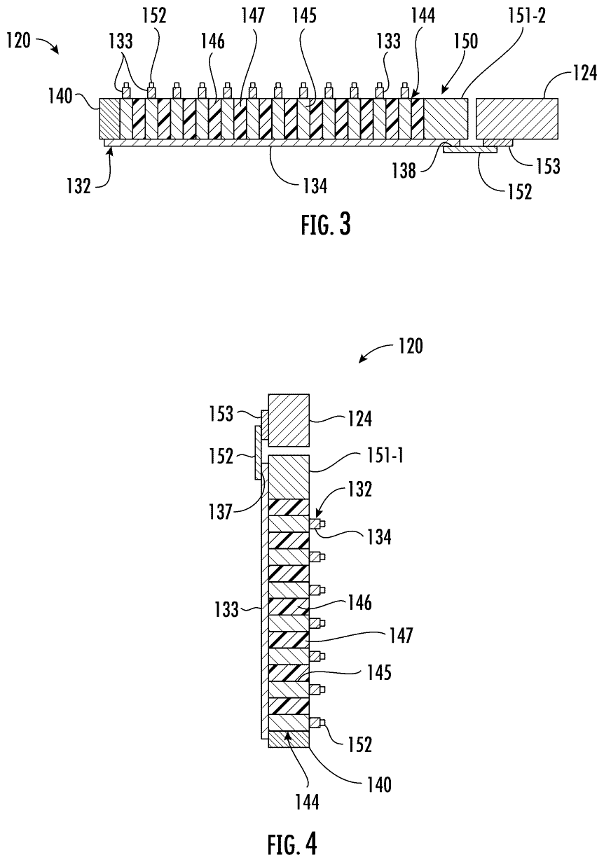

FIGS. 2-4 illustrate portions of an example ultrasound transducer 120. FIG. 2 is a top view of ultrasound transducer 120. FIG. 3 is a sectional view of ultrasound transducer 120 taken along line 3-3 of FIG. 2. FIG. 4 is a sectional view of ultrasound transducer 120 taken along line 4-4 of FIG. 3. FIGS. 2-4 illustrate an example of how Piezo resistive elements may be formed as part of the substrate, of how electrically conductive signal and bias lines may be provided on opposite faces of a transducer array, and how the transducer array may comprise a connector footing that extends along peripheral edges of the substrate. Ultrasound transducer 120 comprises printed circuit board 124, transducer array 128, electrically conductive lines 132, connectors 137, 138, and connector footing 150.

Printed circuit board 124 comprises serves as an interface to provide electrical connections to the transducer array 128. In some implementations, printed circuit board 124 may comprise an electrically insulative board, formed from a material such as FR4. The electrically insulative board may include electrically conductive traces which provide electrical connection to other electrical or electronic components, such as controllers and the like. Electrical control signals are transmitted to the transducer array via the printed circuit board 124.

As shown by FIG. 2, printed circuit board 124 extends along at least two orthogonal peripheral edges of transducer array 128. In some implementations, printed circuit board 124 may surround transducer array 128. In other implementations, printed circuit board 124 may extend along a portion of the outer periphery of transducer array 128.

Transducer array 128 comprises that portion of ultrasound transducer 120 that outputs ultrasound waves and/or that detects echoes from previously emitted ultrasound waves. Transducer array 128 comprises substrate 140, Piezo resistive element array 144 and connector footing 150. Substrate 140 supports Piezo resistive element array 144 and connector footing 150.

Piezo resistive element array 144 comprises an array of Piezo resistive elements 145 arranged in rows and columns, wherein each of the elements 145 is individually actuatable (via electrical signals) so as to stimulate the individual element which results in the individual element 145 vibrating and generating ultrasound waves. Although array 144 is illustrated as comprising seven rows and 12 columns of individual elements 145, in other implementations, array 144 may have a larger number of individual Piezo resistive elements 145 with other numbers of rows and/or columns of such elements 145. In one example implementation, array 144 has a density of at least five Piezo resistive elements 145 per millimeter.

In the example illustrated, Piezo resistive elements 145 are formed in or as part of substrate 140. For example, the layer or layers forming substrate 140 may comprise a layer or panel of Piezo resistive material layer, wherein portions of the panel are removed by a material removal technique (chemical etching, laser ablation, mechanical sawing) so as to dice the layer and form the array 144 of individual Piezo resistive elements 145. Such dicing creates kerfs 146 that space and separate individual Piezo resistive elements 145. In some implementations, the kerfs 146 may be filled with an insulative or dielectric material 147 such as an unfilled epoxy or urethane. In some implementations, the Piezo resistive element array 144 is formed on top of substrate 140 or secured to a top of substrate 140. For example, the array of individual Piezo resistive elements 145 may be patterned on top of an underlying substrate 140.

Electrically conductive lines 132 comprise electrically conductive wires or electrically conductive traces that provide electrical connections to the individual Piezo resistive elements 145 of array 144. Electrically conductive lines 132 comprise signal lines 133 and a bias lines 134 (or ground lines) for each of the individual Piezo resistive elements 145 of array 144. Each individual signal line 133 is electrically connected to an associated individual signal line electrical connector 137 of array 136 for electrical connection to printed circuit board 124. Each individual bias line 134 is electrically connected to an associated individual bias line electrical connector 138 of array 136 for electrical connection to printed circuit board 124. As a result, each individual Piezo resistive element 145 of array 144 may be independently and selectively actuated or electrically stimulated.

In some implementations, the signal lines and a bias lines may be provided on a single face of the array 144 of Piezo resistive elements 145. In the example illustrated, the signal lines 133 and the bias lines 134 are provided on opposite faces of the array 144, making electrical contact with a top and a bottom, respectively, of each of the individual Piezo resistive elements 145.

In some implementations, the electrically conductive lines 132 may be integrally formed as single unitary body with the array of connectors 136. For example, in some implementations, a first electrically conductive sheet may be located along a first face of the array 44 and patterned to form both the signal lines 133 and their associated individual signal line connectors 137. In such an implementation, a second sheet may be located along a second opposite face of array 144 and patterned to form the bias lines 134 and their associated individual bias line connectors 138 of array 36.

In some implementations, the signal lines 133 and the bias lines 134 may be formed from multiple sheets of electrically conductive material, wherein the sheets are patterned (through material removal techniques) to form the signal lines 133 and bias lines 134, wherein the corresponding electrical connectors 137, 138 are independently or separately formed and electrically connected to the signal and bias lines 133 and 134, respectively.

Connector array 136 comprises an array or series of individual, electrically isolated, electrical connectors formed upon or otherwise supported by connector footing 150. The individual electrically isolated electrical connectors 137, 138 are individually connected to an associated signal line 133 or an associated bias line 134 of the electrically conductive lines 32. The individual electrically isolated electrical connectors of array 36 are further electrically connected to printed circuit board 124. In the example illustrated, each of the individual connectors of array 136 comprises an electrical contact pad to which an electrically conductive line 152 is connected. The electrically conductive lines 152 may be connected to the connector array 136 by established bonding techniques such as wire bonding, thin bonding, edge bonding, or the like). The electrically conductive lines 152 are further connected to electrical contact pads 153 of printed circuit board 124. In other implementations, the individual connectors of array 136 may comprise other forms of electrical connectors for serving as an electrical connection between print circuit board 124 and the Piezo resistive elements 145.

Connector footing 150 underlies and supports connector array 136. In some implementations, connector footing 150 is formed from a material (including a single material or multiple materials) different from the material (a single material or multiple materials) forming substrate 140. The material forming connector footing 150 is more robust than the material forming substrate 140 as against the mechanical forces and/or heat that the connector array 136 may experience when being connected to electrically conductive lines 132 and/or electrically conductive lines 152. In some implementations, the substrate 140 is formed from a ceramic material. In some implementations, the substrate 140 is formed from a Piezo resistive material. In such implementations, the at least one connector footing 150 is formed a dielectric material having an electrical conductivity sufficiently small to avoid electrical cross-talk between neighboring electrical contacts, connectors or lines, and a Young's Modulus stiffness of at least 20 GPa. In some implementations, the connector footing 150 may additionally have a low coefficient of thermal expansion (CTE) to reduce alignment error and delamination stresses during fabrication when subjected to temperature excursions.

In one implementation wire bonding settings such as wire feed rate, temperature, contact pressure and wire material (e.g., copper, gold, aluminum and silver) are those commonly used in the art for ultrasound array fabrication. Please supplement particular minimum requirements for particular

In some implementations, the connector footing 150 may be formed from an electrical insulator such as boron nitride which has a Young's Modulus stiffness of 100 GPa and a thermal conductivity of 750 (W/m-k). In some implementations, the connector footing 150 may be formed from other electrically insulating material such as borosilicate glass (80 to 100 GPa), FR-4 (10-25 GPa), alumina nitride (270-350 GPa), alumina (400 GPa) or the like.

In some implementations, connector footing 150 may be formed from the same material as that forming the Piezo resistive elements, but wherein connector footing 150 is solid, and is not a composite, in that it lacks the any gaps or channels (kerfs) cut into the material or filling materials within the kerfs. For example, in some implementations, a solid bar of Piezo resistive material, the same material forming the individual pillars of the Piezo resistive elements, may be mounted, bonded or otherwise joined to outer edge of the portion of substrate 140. In other implementations, a panel or plate of PZT/PMN-PT (55-75 GPa) may have an interior portion diced with a laser or etching to form the Piezo resistive pillars or elements, wherein the kerfs, which are filled with an epoxy or similar material, terminate prior to reaching edges of the panel or plate and wherein the undiced edge portions of the panel or plate has a greater structural integrity and is more robust for underlying and supporting the connector array 136.

In the example illustrated, connector footing 150 is formed by molding, bonding or otherwise securing a layer or bar of the material that forms the connector footing 150 to a peripheral edge of the substrate 140 or the peripheral edge of the array 144 of transducer elements 145. In the example illustrated, the connector footing 150 is configured to support connectors or connection locations on opposite faces, adjacent to or along opposite faces of the substrate 140 and the array 144 of Piezo resistive elements 145. In the example illustrated, 1 the connector footing 150 may comprise footing segments 151-1 and 151-2 (collectively referred to as segments 151). Footing segments 151 extend along opposite and/or orthogonal edges of the substrate 140. In some implementations, the connector footing 150 may comprise a continuous footing 150 that surrounds the substrate 140 and/or the array 144 of Piezo resistive elements 145.

In the example illustrated, each of footing segments 151 has a thickness substantially equal to thickness substrate 141 and/or vertical height of each of Piezo resistive elements 145. As result, the forming of electrically conductive lines 132 on the opposite face of substrate 140 may be better facilitated. However, in other implementations, one or both of footing segments 151 may alternatively have a thickness different than that of substrate 140 such that one or both footing segments 151 is recessed below or projects above either or both of the top face of substrate 140 or the bottom surface or face of substrate 140. In some implementations, one or both of footing segments 151 may have a thickness equal to that of substrate 140 but offset such that the segment is recessed along one face and projects above the opposite face of substrate 140.

As schematically shown in FIG. 2, printed circuit board 124 is electrically connected to transducer array 128 at connection locations 154 (schematically represented by darkened circles) on connectors 137, 138. The connectors 137,138 or connecting locations 154 may undergo high levels of mechanical force and/or heat as electrically conductive wires or traces are bonded or otherwise connected to the transducer array at the connection locations. Because such connection locations 154 are supported by connector footing 150, rather than the potentially weaker material of substrate 140, the risk that those mechanical forces and/or heat may damage the transducer array is reduced. Connector footing 150 reduces the likelihood of damage to the transducer array 128 during bonding or other connection of the transducer array to the printed circuit board at the connection locations 154. Connector footing 150 may facilitate the use of smaller or thinner transducer arrays or the substrates that provide the array of Piezo resistive elements 145. Connector footing 150 may facilitate a higher density of Piezo resistive elements for enhanced transducer performance.

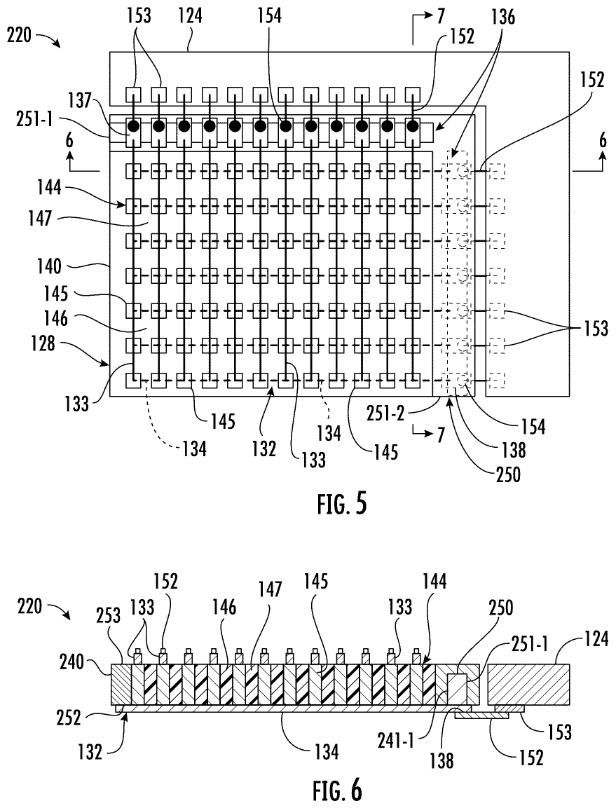

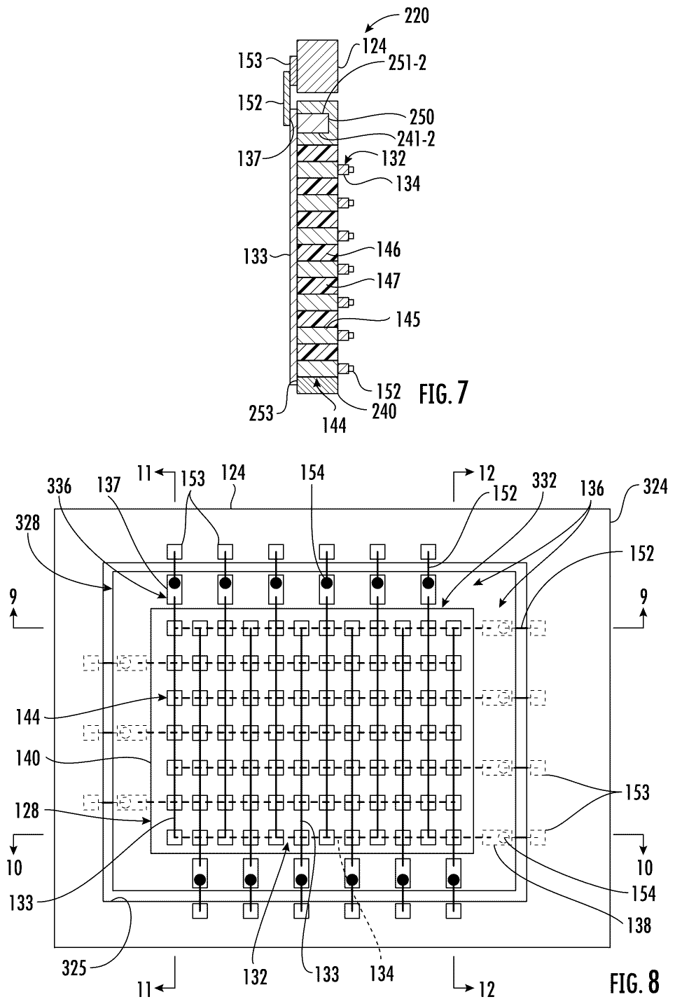

FIGS. 5-7 illustrate portions of an example ultrasound transducer 220. FIGS. 5-7 illustrate an example of how a connector footing may be provided in a groove or channel formed in the substrate. Ultrasound transducer 220 is similar to ultrasound transducer 120 described above except that ultrasound transducer 120 comprises substrate 240 and connector footing 250 in place of substrate 140 and connector footing 150, respectively. Those remaining components of ultrasound transducer 220 which correspond to components of ultrasound transducer 120 are numbered similarly.

Substrate 240 is similar to substrate 140 described above except that outer perimeter portions of substrate 140 comprise recesses 241-1, 241-2 (collectively referred to as recesses 241). Recess 241-1 extends into substrate 240 from a bottom face 252 of substrate 240. Recess 241-2 extends into substrate 240 from a top face 253 of substrate 240. Recesses 241 do not extend completely through the layer or sub layers of substrate 240 such that a portion substrate 240 forms a floor of the recess 241.

Although recesses 241 are illustrated as being formed inside of the peripheral edge of substrate 240, in some implementations, recesses 241 may be formed along the peripheral edge, wherein a portion of the peripheral edge or side is removed or not provided such that each of recesses 241 forms a shoulder having an inner side wall and a floor (no outer side wall) along the periphery of substrate 240. Although recesses 241 are each illustrated as elongate grooves or channels, wherein recess 241-1 extends above and opposite to each of bias line connectors 138 and wherein recess 241-2 extends below and opposite to each of signal line connectors 137, in other implementations, recesses 241 may comprise individual craters or depressions, wherein each of the individual depressions extends opposite to an individual signal line or bias line connector or opposite to a portion of the signal or bias line connectors.

In one implementation, recesses 241 are formed by laser cutting or ablation. In other implementations, recesses 241 may be formed by other material removal techniques such as mechanical sawing or chemical etching. In some implementations, recess 241 may be formed during the molding of substrate 240.

Connector footing 250 is similar to connector footing 150 described above except that, rather than extending along a peripheral edge of substrate 140, wherein connector footing 150 forms entire side edges of transducer array 128, connector footing 250 fills recesses 251. Connector footing 250 comprises footing segments 251-1, 251-2 (collectively referred to as footing segments 251). Footing segment fills recess 241-1. Similarly, footing segment 251-2 fills recess 241-2.

In the example illustrated, the exposed surfaces of segments 251 (those surfaces adjacent to the signal and bias line connectors 137, 138) are substantially level or flush with the bottom and top faces 252, 253, respectively, of substrate 240. As result, the forming of electrically conductive lines 134 and 133 and connectors 137, 138 may be enhanced. In other implementations, the exposed surface of segments 251 may be partially recessed within recesses 241 or may project beyond recesses 241.

In some implementations, connector footing 250 may be formed from material different than the material forming the Piezo resistive elements 145. In implementations where a dicing saw is used to form the kerfs, the kerfs may extend completely to the edges of the PCT/PMN-PT panel such that the solid, more monolithic, un-diced connector footing 250 is formed by forming recesses 241 (shown as a groove or channel) in the diced portion of the panel or plate just inside of the edges of the diced panel or plate and filling the groove or channel with the PCT/PMN-PT material or the other connector footing materials described above.

In implementations where a groove or channel is formed along an inside of the edges of the diced panel or plate and wherein the groove or channel is subsequently filled with material that serves as the conductor footing, the groove or channel (and the corresponding width of the material filling the groove or channel and forming the connector footing) may have a width larger than the width of the kerfs that separate the Piezo resistive elements in the diced portion of the panel or plate. The width of the channel and the corresponding width of the conductor footing material that fills the channel may be sufficiently wide to support the connector array 136.

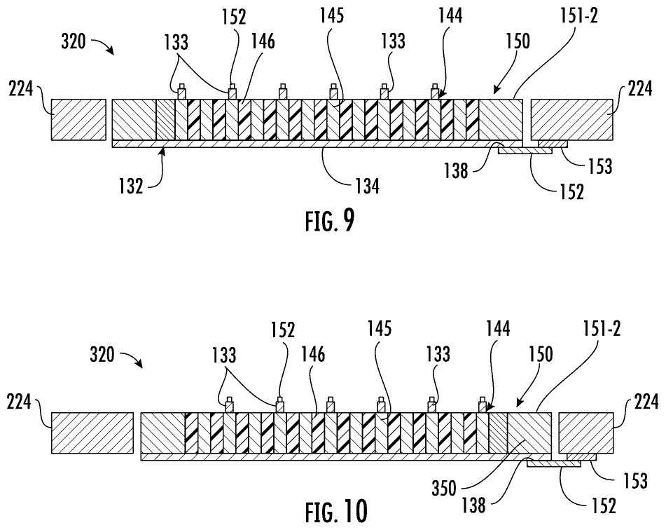

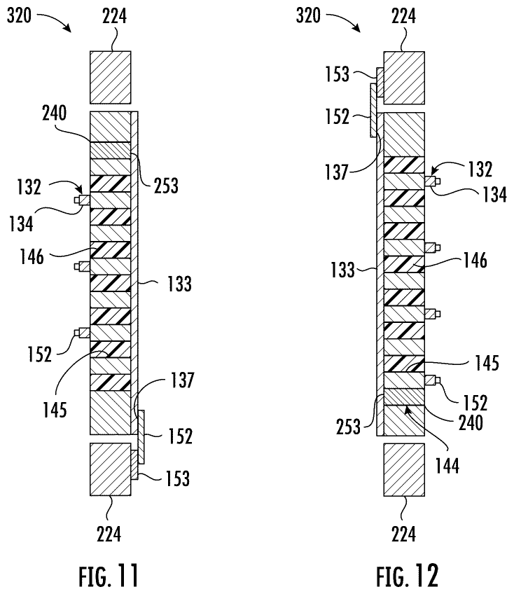

FIGS. 8-12 illustrate portions of an example ultrasound transducer 320. FIGS. 8-12 illustrate an example of how a connector footing may frame an array of Piezo resistive elements to support bias and signal line connectors around the array for enhanced Piezo resistive element density. Ultrasound transducer 320 is similar to ultrasound transducer 120 described above except that ultrasound transducer 320 comprises circuit board 324, electrically conductive lines 332, connector array 336 and connector footing 350 in place of printed circuit board 124, electrically conductive lines 132, connector array 136 and connector footing 150, respectively. Those remaining components of ultrasound transducer 320 which correspond to components of ultrasound transducer 120 are numbered similarly.

Printed circuit board 324 is similar to circuit board 124 except printed circuit board 324 comprises an opening 325 in which transducer array 328 is received. Opening 325 facilitates direct electrical connection between printed circuit board 325 and transducer array 128 from all sides of transducer array 128. In some implementations, any gaps between transducer array 128 and the interior sides of opening 325 may be filled with a filler, adhesive or the like, securing transducer array 328 to printed circuit board 324. In some implementations, transducer array 128 and printed circuit board 324 may be supported by an underlying or overlying panel or substrate.

Electrically conductive lines 332 are similar to electrically conductive lines 132 described above except that the signal lines 133 extend from opposite sides of array 144, wherein a first portion of the signal lines 133 are associated with signal line connectors 137 on a first side of array 144 and a second portion of signal lines 133 are associated with signal line connectors 137 on a second opposite side of array 144 and are interleaved amongst the first portion of signal lines 133. In the example illustrated, signal line connectors 137 on one side of array 144 are electrically connected to those signal lines 133 that extend across and that are connected to odd-numbered columns of Piezo resistive elements 145. Signal line connectors 137 on the opposite side of array 144 are electrically connected to those signal lines 133 that extend across and that are connected to even numbered columns of Piezo resistive elements 145.

Similarly, bias lines 130 extend from opposite sides of array 144, wherein a first portion of the bias lines 134 are associated with bias line connectors 138 on a first side of array 144 and a second portion of bias lines 134 are associated with bias line connectors 138 on a second opposite side of array 144 and are interleaved amongst the first portion of bias lines 134. In the example illustrated, bias line connectors 138 on one side of array 144 are electrically connected to those bias lines 134 that extend across and that are connected to odd-numbered rows of Piezo resistive elements 145. Bias line connectors 138 on the opposite side of array 144 are electrically connected to those bias lines 134 that extend across and that are connected to even numbered rows of Piezo resistive elements 145. Such interleaving of the signal lines on a first face of the substrate and such interleaving of the bias lines on a second opposite face of the substrate facilitates larger connectors 137, 138, a more dense or compact arrangement of signal and bias lines 133, 134 and a more dense and compact arrangement of Piezo resistive elements 145.

Connector footing 350 underlies or overlies (extends opposite to) each of the signal line connectors 137 and each of the bias line connectors 138. Connector footing 350 extends along and is secured to or supported by more than three sides of substrate 140. In the example illustrated in which substrate 140 has four sides, connector footing 350 extends along Like connector footing 150, connector footing 350 extends along each of the four sides, framing substrate 140 and the array 144 of Piezo resistive elements 145. In the example illustrated, connector footing 350 comprises a continuous rectangular frame that continues extends about substrate 140 and array 144. In other implementations, connector footing 350 may be comprised segments that extend along each of the sides of substrate 140 and array 144.

As with connector footing 150, connector footing 350 may be formed from a more robust material than that of substrate 140 or the array of Piezo resistive elements 145, or may be formed from the same piezo-resistive material of elements 145, but being solid without kerfs. Connector footing 350 may be formed from the same materials set described above with respect to the construction of connector footing 150. Connector footing 350 enhances the durability of transducer array 128 during the connection of connectors 137, 138 to lines 133, 134 and/or to lines 152 which electrically connect connectors 137, 138 to the printed circuit board 124.

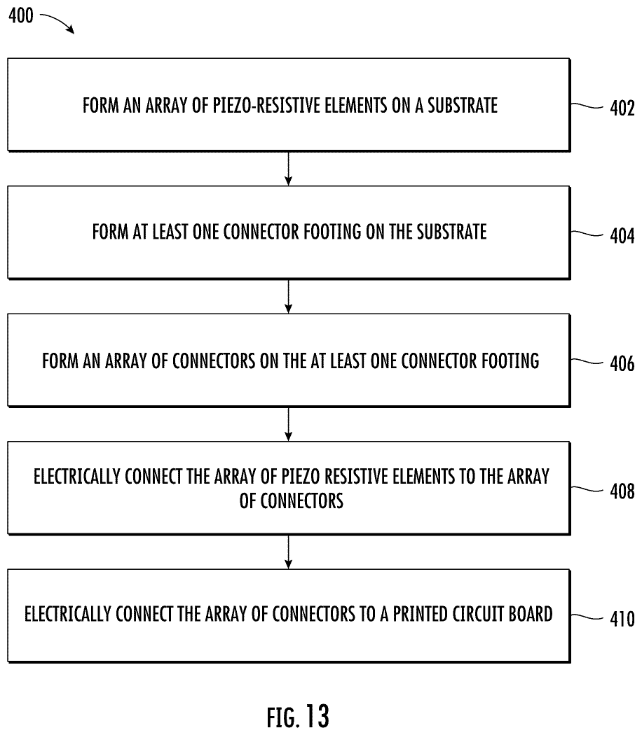

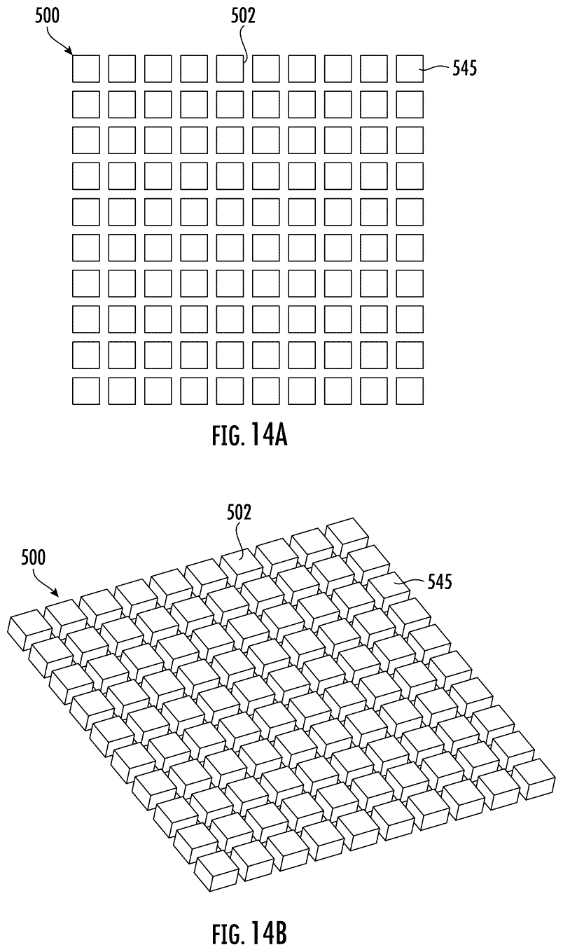

FIG. 13 is a flow diagram of an example method 400 for forming an ultrasound transducer. FIGS. 14A, 14B, and 15-23 illustrate one example implementation of method 400. As should be appreciated, method 400 may be carried out in various other manners so as to form an ultrasound transducer.

As indicated by block 102 in FIG. 13, an array of Piezo resistive elements is formed on a substrate. FIGS. 14A and 14B illustrate 1 Example way of forming the array of Piezo resistive elements, wherein an initial substrate plate 500 formed from a Piezo resistive material such as PZT or PMN-PT is provided. The plate may have a thickness greater than final substrate plate thickness to facilitate subsequent grinding steps to maintain a flat profile of the plate 500.

As shown by FIGS. 14A and 14B, the plate 500 is diced, such as with a dicing saw or laser, to form orthogonal patterns of kerfs 502 that separate rows and columns of individual Piezo resistive elements 545. For purposes of illustration, the size of the kerfs 502 and Piezo resistive elements 545 are enlarged. In practice, the size of the kerfs 502 and individual Piezo resistive elements 545 may be much smaller to provide a greater density of Piezo resistive elements, such as at least five Piezo resistive elements per square millimeter. Moreover, the number of Piezo resistive elements may be much larger than that being shown.

In some implementations, the grid-like pattern is cut to a full depth on a first pass such as when the plate is fully supported by an underlying flat plate. In some implementations, the grid-like pattern is cut partially through the plate from one side, wherein the kerfs are filled with an electrically insulating or dielectric material. Thereafter, the plate is flipped over, and the corresponding grid-like pattern is cut partially through the plate 500. Said another way, the kerfs being made after the plate is flipped over are aligned with the existing kerfs that partially extend through the thickness of the plate, wherein such kerfs have a sufficient depth so as to intersect the prior filled kerfs.

As shown by FIG. 15, the kerfs 502 of the diced plate 500 are filled with a material that is sufficiently flexible or soft to reduce vibration cross-talk between individual Piezo resistive elements 545. In those implementations where the partial depth kerfs made from a first side of the plate or partially filled, the partial depth kerfs made from the second side of the plate are filled. Examples of materials that may be used to fill the kerfs include unfilled epoxy or urethane. In some implementations, metal oxides, glass micro balloons and other powders may be added to serve as scatterers to reduce inter-element crosstalk. Glass micro balloons and ceramic powders may further assist in reducing shrinkage and the coefficient of thermal expansion of such fillers. Once filled, the initial diced plate with the fillers may be ground to enhance a flatness of the plate 500.

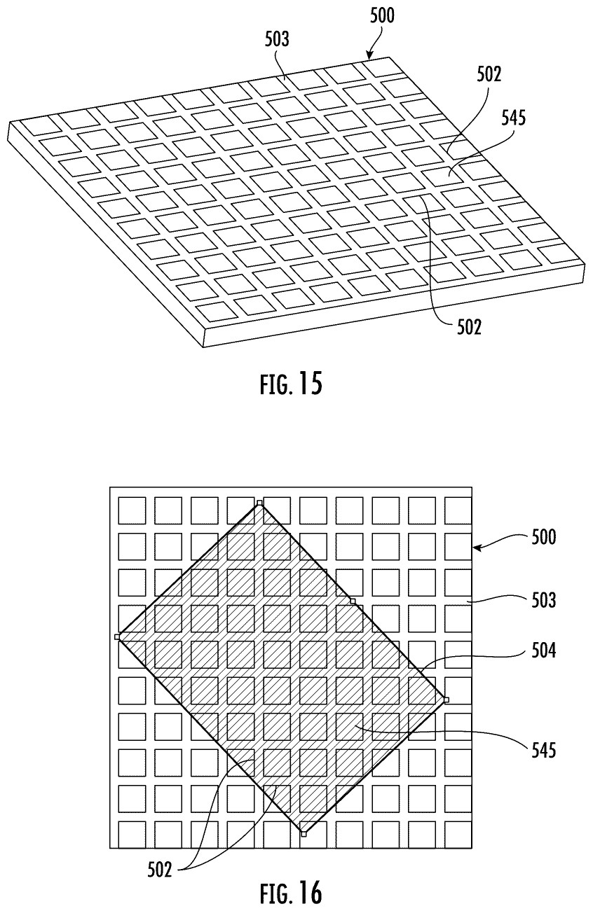

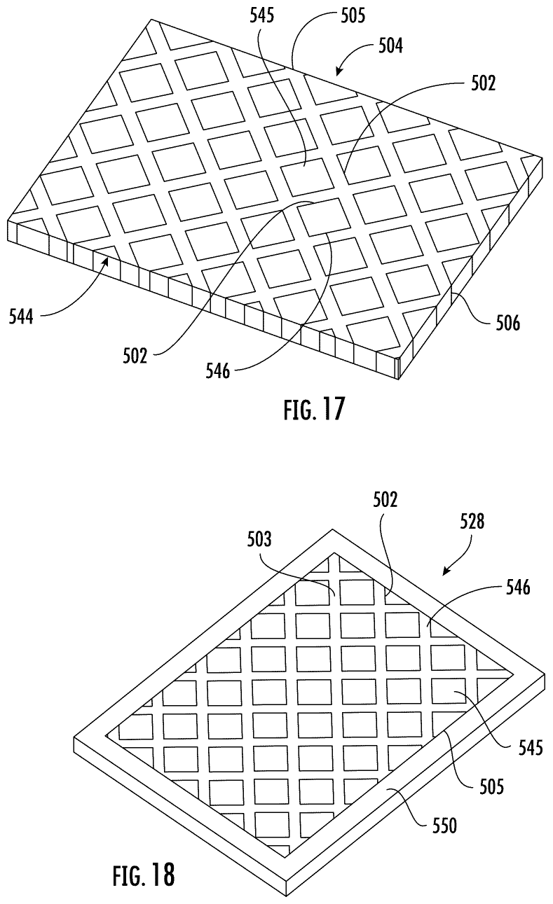

As shown by FIG. 16, in some implementations, the diced and filled plate 500 is trimmed to its final shape, forming panel 504 (shown in FIG. 17). In the example illustrated, the diced and filled plate 500 is trimmed out at a non-parallel angle to the original pattern. Said another way, the plate 500 is trimmed such that the orthogonal filled kerfs 502, separating the Piezo resistive elements 545, are oblique to the sides 505, 506 of the final panel 504. The oblique angles of the kerfs and the angled Piezo resistive elements 545 may assist in breaking up the diced pattern symmetry (row to row performance variability) and may reduce lateral modes (mechanical sheer waves).

As indicated by block 404 of FIG. 13, at least one connector footing is formed on the substrate. In the example illustrated by FIG. 18, connector footing 550 is provided or formed about panel 504 to form transducer array 528. Connector footing 550 is similar to connector footing 350 described above. In some implementations, connector footing 550 may be formed from a single material. In some implementations, connector footing 650 may be formed from a mixture of multiple different materials or a stack of different layers of the same or different materials. In some implementations, connector footing 550 is mounted, bonded or otherwise joined to panel 504.

In the example illustrated, plate 500 is diced from edge to edge, wherein the connector footing 550 is formed by joining connector footing 550 to the diced plate, after kerf filling. In other implementations, connector footing 550 may be formed along a perimeter of panel 504 by terminating by only dicing an interior portion of plate 500, wherein the undiced outer edge portions of plate 500 remains solid with the undiced surface areas being much greater than the surface areas of the individual pillars or diced portions of plate 500. The solid and more monolithic nature of the outer edge portions of plate 500 may serve as connector footing 550.

Connector footing 550 frames panel 504, extending along each of the sides of panel 504 and the formed array 544 of Piezo resistive elements 545. In the example illustrated, connector footing 550 has a thickness substantially equal to the thickness of panel 504. Such thickness enhances or facilitates subsequent fabrication of the ultrasound transducer. In other implementations, connector footing 550 may project above or be recessed below the top or bottom faces of panel 504.

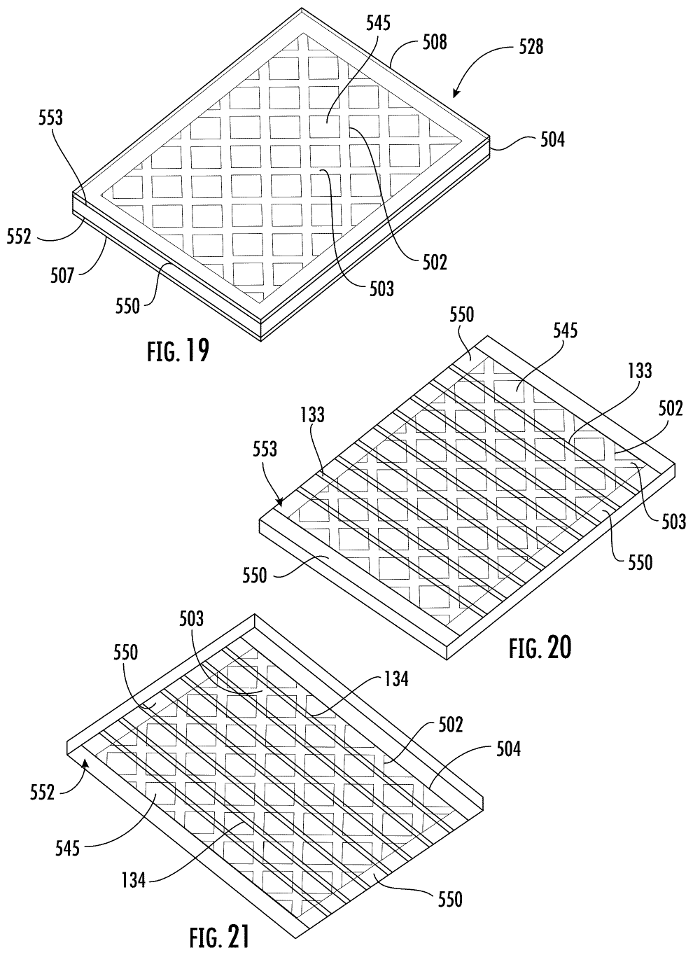

As indicated by block 406 in FIG. 13, an array of connectors is formed on the at least one connector footing. As indicated by block 408, the array of Piezo resistive elements are electrically connected to the array of connectors. In the example shown in FIGS. 19-21, the array of connectors on the connector footing 550 and the signal and bias lines that connect the Piezo resistive elements 545 to the connectors are formed together, integrally formed as a single unitary body. As shown by FIG. 19, an electrically conductive bottom panel, sheet or layer 507 is formed on the bottom face 552 of panel 504. Layer 507 is in electrical connection with a bottom of each of Piezo resistive elements 545. An electrically conductive top panel, sheet or layer 508 is likewise formed on the top face 553 of panel 504 (transducer array 528). Layer 508 is in electrical connection with a top of each of Piezo resistive elements 545. Each of layers 507, 508 overlies connector footing 550. In some implementations, panel 504 is metallized to form layers 507, 508. In other implementations, layers 507, 508 may be formed upon the opposite face of panel 504 in other fashions.

As shown by FIG. 20, signal lines 133 and their corresponding connectors 138 are formed on face 553 of panel 504. Each of signal lines 133 is in electrical contact with a series underlying Piezo resistive elements 545. In the example illustrated, the pitch of the signal lines 133 is such that no individual Piezo resistive element 545 is in electrical contact with more than one signal line 133. In other implementations, the pitch of the signal lines 133 (and/or the size and location of the Piezo resistive elements 545) may be such that more than one signal line 133 is in contact with an individual Piezo resistive element 545. In such implementations where multiple signal lines 133 may be in electrical contact with an individual Piezo resistive element 545, one or more of the multiple signal lines 133 that are in contact with the individual Piezo resistive element 545 may be selectively used to transmit electrical current and actuate or stimulate the individual Piezo resistive element 545.

In the example illustrated, the substantially imperforate electrically conductive layer 508 is patterned to form signal lines 133 and connectors 137. In some implementations, layer 508 is patterned through a material removal process such as laser ablation, mechanical sawing or masking in combination with chemical etching. In yet other implementations rather than patterning and imperforate sheet of electrically conductive material to form signal lines 133 and connectors 137, signal lines 133 and/or connectors 137 may themselves be patterned directly upon face 553 of panel 504. For example, electrically conductive material may be sputtered or otherwise deposited in a pattern fashion using a mask or the like to form signal lines 133 and/or connectors 137. In some implementations, signal lines may be provided as part of a sheet of dielectric material which supports the electrically conductive signal lines, wherein the sheet is laminated or otherwise secured to the face 553 of panel 504 with the signal lines being registered with the elements 545. In yet other implementations, signal lines 133 and connectors 137 may be formed in other fashions.

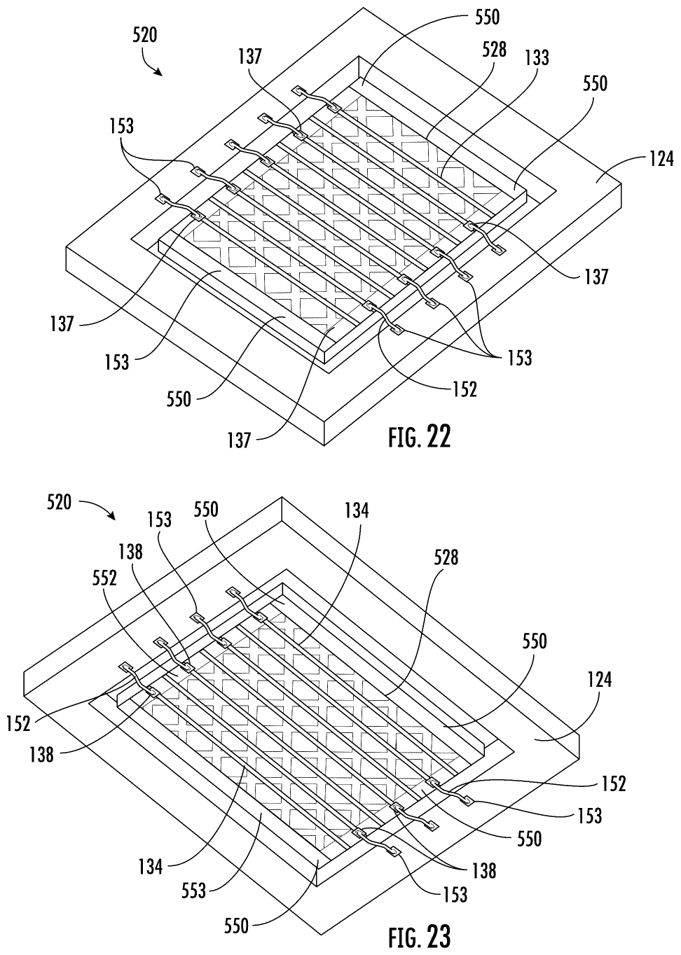

As shown by FIG. 21, bias lines 134 and their corresponding connectors 137 are formed on the opposite face 552 of panel 504. Each of bias lines 134 is in electrical contact with a series underlying Piezo resistive elements 545. In the example illustrated, the pitch of the bias lines 134 is such that no individual Piezo resistive element 545 is in electrical contact with more than bias line 134. In other implementations, the pitch of the bias lines 134 (and/or the size and location of the Piezo resistive elements 545) may be such that more than one bias line 134 is in contact with an individual Piezo resistive element 545. In such implementations where multiple bias lines 134 may be in electrical contact with an individual Piezo resistive element 545, one or more of the multiple bias lines 134 that are in contact with the individual Piezo resistive element 145 may be selectively used to transmit electrical current and actuate or stimulate the individual Piezo resistive element 545.

In the example illustrated, bias lines 134 and connectors 138 are formed by patterning the electrically conductive layer 507 provided on face 552 of panel 504. In some implementations, layer 507 is patterned through a material removal process such as laser ablation, mechanical sawing or masking in combination with chemical etching. In yet other implementations, rather than patterning an imperforate sheet of electrically conductive material to form bias lines 134 and connectors 138, bias lines 134 and/or connectors 138 may themselves be patterned directly upon face 552 of panel 504. For example, electrically conductive material may be sputtered or otherwise deposited in a pattern fashion using a mask or the like to form bias lines 134 and/or connectors 138. In some implementations, bias lines 134 may be provided as part of a sheet of dielectric material which supports the electrically conductive bias lines, wherein the sheet is laminated or otherwise secured to the face 552 of panel 504 with the bias lines being registered with the elements 545. In yet other implementations, bias lines 134 and connectors 138 may be formed in other fashions.

Signal lines 133 and bias lines 134 extend on opposite faces of panel 504 in orthogonal directions. In the example illustrated, signal lines 133 extend inwardly from opposite sides of panel 504 on a first face of panel 504 and are interleaved with one another in a fashion similar to the interleaving shown and described above with respect to ultrasound transducer 320. Likewise, in the example illustrated, bias lines 134 extend inwardly from opposite sides of panel 504 on an opposite second face of panel 504 and are interleaved with one another in a fashion similar to the interleaving shown and described above with respect to ultrasound transducer 320. In other implementations, signal lines 133 and such or bias lines 134 may not be interleaved and may not have their corresponding connectors 137, 138 on opposite sides of panel 504, similar to its the signal lines and bias lines shown and described above with respect to ultrasound transducers 120 and 220.

As indicated by block 410 in FIG. 13, the array of connectors are connected to a printed circuit board. FIGS. 22 and 23 illustrate an example of how the connectors may be electrically connected to a printed circuit board. FIG. 22 illustrates the electrical connection of the signal line connectors 137 being electrically connected to printed circuit board 124. In the example, electrically conductive lines 152, in the form of wires, each have a first end bonded to an associated one of connectors 137 and a second end bonded to an electrical connector 153, in the form of an electrical contact pad, on a top face of printed circuit board 124. Similarly, FIG. 23 illustrates the electrical connection of the bias line connectors 138 being electrically connected to printed circuit board 124. In the example, electrically conductive lines 152, in the form of wires, each have a first end bonded to an associated one of connectors 138 and a second end bonded to an electrical connector 153, in the form of an electrical contact pad, on a bottom face of printed circuit board 124. Because connector footing 550 supports connectors 137 and 138 and because connector footing 550 is formed from a more robust material as compared to the material or materials of Piezo resistive elements 545, connector footing 550 reduces the likelihood of damage to the transducer array 528 as such connections are being made.

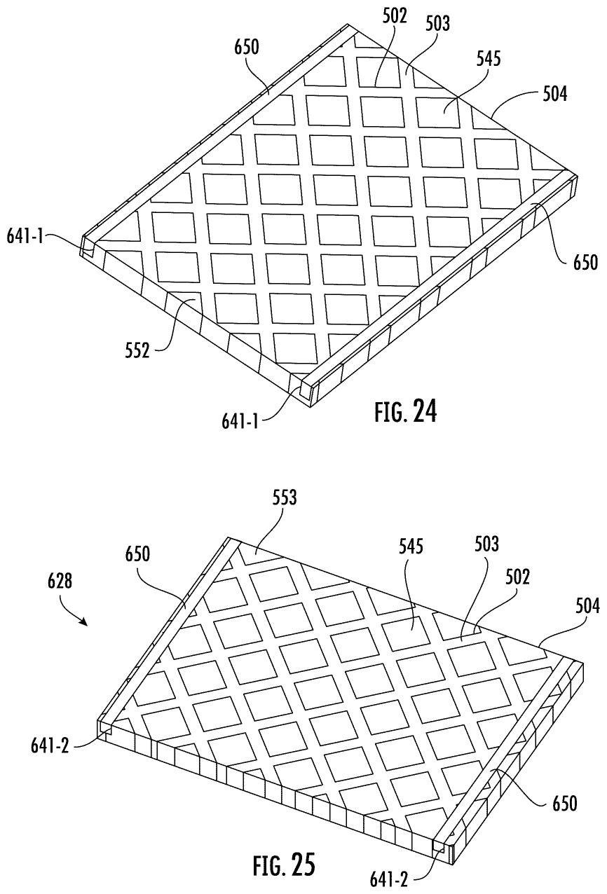

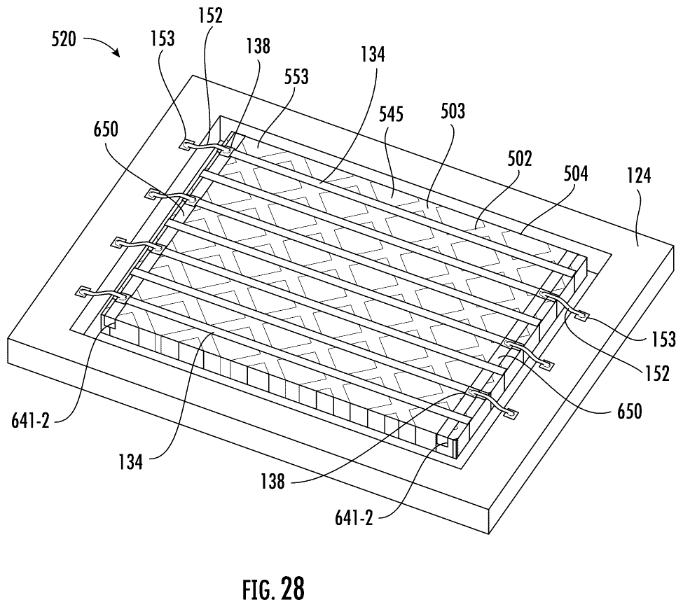

FIGS. 24-28 illustrate another example implementation of method 400 described above with respect to FIG. 13. With this implementation, the forming of array of Piezo resistive elements on the substrate set forth in block 402 may be similar to the forming of the array of resistive elements on the substrate as described above with respect to FIGS. 14-17. FIGS. 24 and 25 illustrate another example way of forming the at least one connector footing on the substrate as set forth in block 404 of FIG. 13.

As shown by FIG. 24, recesses, in the form of channels 641-1, are formed in face 553 of panel 504 along and inwardly of opposite side edges of panel 504. The channel 641-1 do not extend completely through panel 504, such that a portion of panel 504 forms a floor of channel 641-1. In the example illustrated, interior surfaces of the channel 641-1 may be formed by portions that are formed from the Piezo resistive material forming Piezo resistive elements 545 and from the material 503 that fills kerfs 502. Each of the channels 641-1 may be similar to the recess 241-1 described above.

As further shown by FIG. 24, each of channels 641-1 is filled with one or more materials, different than that of the material forming Piezo resistive elements 545 or the kerf filling material 503. In the example illustrated, the one or more materials filling channel 641-1 forms two opposite segments of the connector footing 650. In some implementations, connector footing 650 may be formed from a single material, such as those described above with respect to connector footing 150. In some implementations, connector footing 650 may be formed from a mixture of multiple different materials or a stack of different layers of the same or different materials. In some implementations, the material filling channel 641-1 may be substantially flush with face 552 of panel 504. In other implementations, the material filling channel 641-1 may be recessed below or may project above face 552 of panel 504. As described above, the particular material chosen for connector footing 650 may vary depending upon the method by which the subsequently formed connectors, formed on top of connector footing 650, are to be connected to those wires or other connectors associated with printed circuit board 124 and/or the signal and bias lines (when separately formed).

As shown by FIG. 25, recesses, in the form of channels 641-2, are formed in face 552 of panel 504 along and inwardly of opposite side edges of panel 504. Channels 641-2 are orthogonal to channels 641-1. The channels 641-2 do not extend completely through panel 504, such that a portion of panel 504 forms a floor of channel 641-2. In the example illustrated, interior surface of the channel 641-2 may be formed by portions that are formed from the Piezo resistive material forming Piezo resistive elements 545 and from the material 503 that fills kerfs 502. Each of the channels 641-2 may be similar to the recess 241-2 described above.

As further shown by FIG. 25, each of channels 641-2 is filled with one or more materials, different than that of the material forming Piezo resistive elements 545 or the curve filling material 503. In the example illustrated, the one or more materials filling channel 641-2 forms two opposite segments of the connector footing 650. In some implementations, connector footing 650 may be formed from a single material, such as those described above with respect to connector footing 150. In some implementations, connector footing 650 may be formed from a mixture of multiple different materials or a stack of different layers of the same or different materials. In some implementations, the material filling channels 641-2 may be substantially flush with face 552 of panel 504. In other implementations, the material filling channel 641-2 may be recessed below or may project above face 552 of panel 504. As described above, the particular material chosen for connector footing 650 may vary depending upon the method by which the subsequently formed connectors, formed on top of connector footing 650 are to be connected to those wires or other connectors associated with printed circuit board 124 and/or the signal and bias lines (when separately formed).

In the example illustrated, channels 641-1 and 641-2 are formed by a material removal technique, such as laser ablation, mechanical sawing, chemical etching or the like. In other implementations, channels 641-1 and 641-2 may be formed during the forming of panel 504. For example, channels 641-1 and 641-2 may be formed by molding or material additive techniques. In some implementations, multiple spaced individual recesses, such as craters and depressions may be formed inwardly of an along the opposite edges to form connector footing 650.

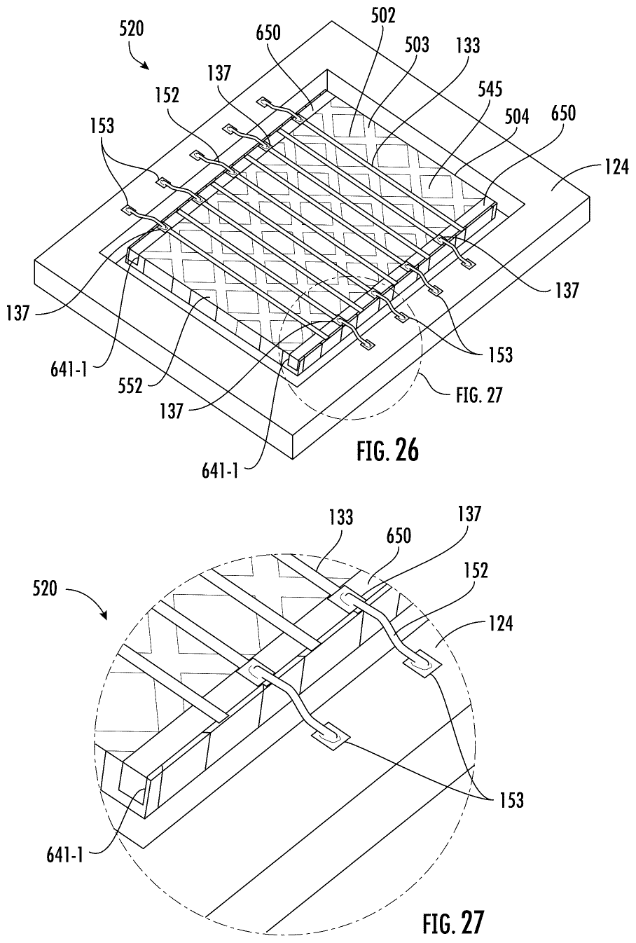

The remaining steps set forth in blocks 406, 408 and 410 of method 100 of FIG. 13 may be carried out in a fashion similar to that described above with respect to FIGS. 19-23. As shown by FIGS. 26 and 27, the signal lines 133 and their corresponding connectors 137 are formed upon face 552 of panel 504 and the bias lines 134 and their corresponding connectors 138 are formed upon face 553 of panel 504. The forming of such signal lines 133, connectors 137, bias lines 134 and connectors 138 may be formed in a manner similar to that described above with respect to FIGS. 19-21.

As shown by FIGS. 26 and 27, the resulting transducer array 628 may be positioned within printed circuit board 124. Thereafter, the array of connectors may be connected to printed circuit board 124 as set forth in block 410 of method 400 of FIG. 13. Such electrical connection may be carried out in a fashion similar to that described above with respect to FIGS. 22 and 23.

In some implementations, the material or materials forming connector footing 650 may vary depending upon the manner by which connectors 133 and 134 are being electrically connected to printed circuit board 124. Likewise, in those implementations where connectors 133 and 134 are formed independent of the formation of signal 133 and bias lines 134 such that connectors 133 and 134 must also be connected to the signal lines 133 and bias lines 134, respectively, the material or materials forming connector footing 650 may vary depending upon the manner of such connection.

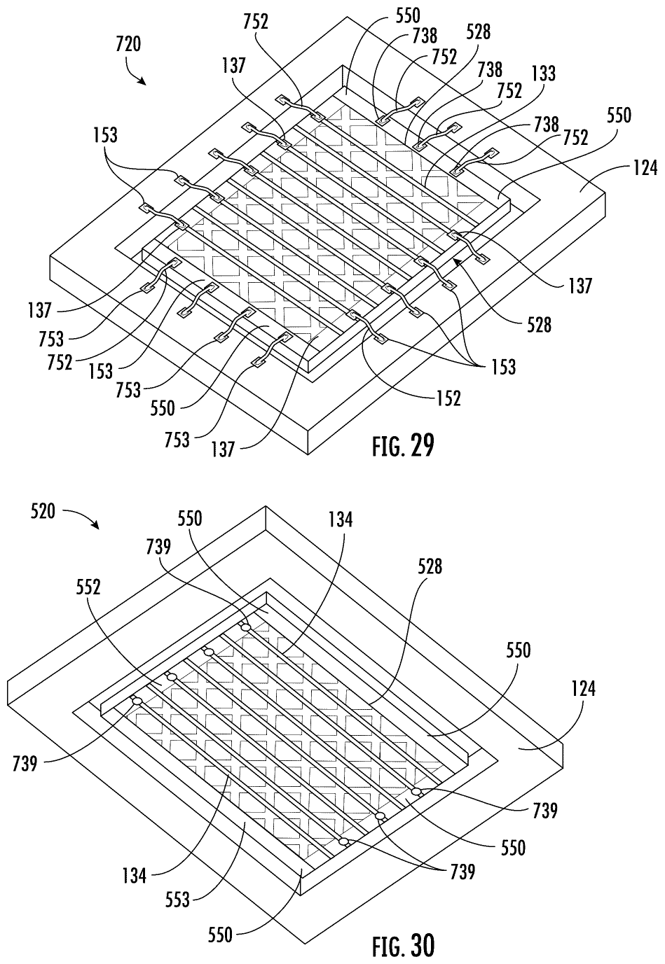

FIGS. 29 and 30 illustrate portions of an example ultrasound transducer 720. FIGS. 29 and 30 illustrate an example of how a transducer array may be provided with electrically conductive vias such that the printed circuit board may be electrically connected to signal lines and bias lines of the transducer array by connector arrays supported by connector footings on one face of the transducer array. Ultrasound transducer 720 is similar to ultrasound transducer 520 shown and described above with respect to FIGS. 22 and 23 except that ultrasound transducer 720 additionally comprises electrically conductive vias 739 (shown in FIG. 30) and comprises electrical connectors 738, electrically conductive lines 752 and electrically conductive contact pads 753 in place of electrical connectors 138, electrically conductive lines 152 and electrically conductive contact pads 153, respectively, on the two opposite short ends of the ultrasound transducer 720. Those remaining components of ultrasound transducer 720 correspond to components of ultrasound transducer 520 are numbered similarly.

Electrically conductive vias 739 comprise openings or passages that extend through connector footing 550 and which are filled or lined with an electric conductive material. In some implementations, the vias 739 may be formed by laser drilling, wherein the electrically conductive materials may be deposited in or along the interiors of the passages during the forming of the metal layers on either of the faces (shown in FIG. 19). In some implementations, vias 739 may alternatively comprise openings or passages that extend through end portions of the substrate of transducer array 528 and which are filled or lined with electrically conductive material. Each of electrically conductive vias 739 is electrically connected to one of the bias lines 134 on one face of transducer 720 and is selectively connected to a corresponding one of electrical connectors 738 on the opposite face of transducer 720.

The electrical connectors 738, electrically conductive lines 752 and electrically conductive contact pads 753 are similar to connectors 138, conductive lines 152 and contact pads 153, respectively, except that each is formed on an opposite face of transducer 720 as compared to transducer 520. As a result, all of the electrical connectors, all of the electrically conductive lines and all of the electrical contact pads associated with printed circuit board 124 are on a single side or face of printed circuit board 124 and a single side or face of transducer array 528. Because such electrical connections occur on a single face of the ultrasound transducer, easier fabrication of transfer 720 may be facilitated.

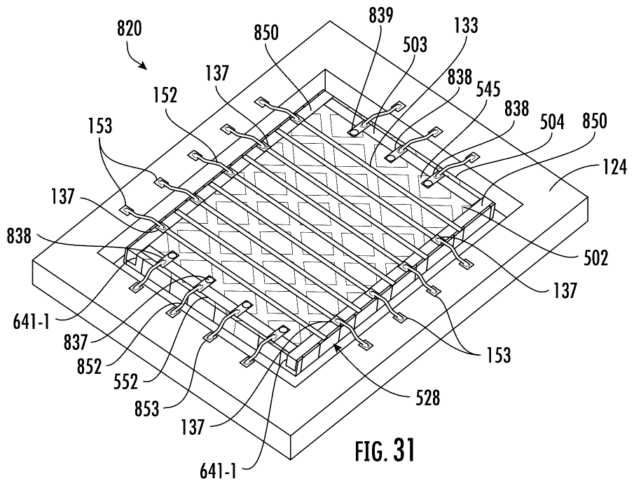

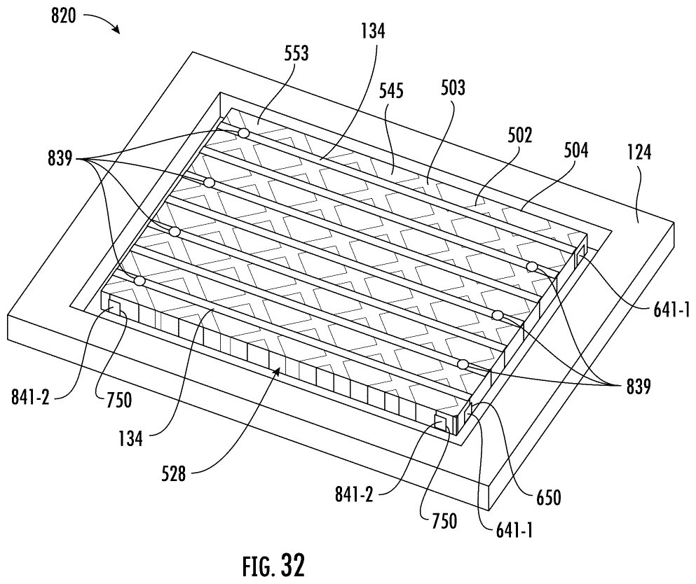

FIGS. 31 and 32 illustrate portions of an example ultrasound transducer 820. FIGS. 31 and 32 illustrate an example of how a transducer array may be provided with electrically conductive vias such that the printed circuit board may be electrically connected to signal lines and bias lines of the transducer array by connector arrays supported by connector footings on one face of the transducer array. Ultrasound transducer 820 is similar to ultrasound transducer 520 shown and described above with respect to FIGS. 26-28 except that ultrasound transducer 820 additionally comprises electrically conductive vias 839 and comprises connector footing 850, electrical connectors 738, electrically conductive lines 752 and electrically conductive contact pads 753 in place of connector footing 650, electrical connectors 138, electrically conductive lines 152 and electrically conductive contact pads 153, respectively, on the two opposite short ends of the ultrasound transducer 820. Those remaining components of ultrasound transducer 820 correspond to components of ultrasound transducer 520 of FIGS. 26-28 are numbered similarly.

Electrically conductive vias 839 comprise openings or passages that extend through end portions of the substrate of transducer array 528 and which are filled or lined with electrically conductive material. and which are filled or lined with an electric conductive material. In some implementations, the vias 839 may be formed by laser drilling, wherein the electrically conductive materials may be deposited in or along the interior of the passages during the forming of the metal layers on either of the faces (shown in FIG. 19). In some implementations, vias 839 may alternatively comprise openings or passages that extend through connector footing 550 and which are filled or lined with electrically conductive material. Each of electrically conductive vias 839 is electrically connected to one of the bias lines 134 on one face of transducer 820 and is electrically connected to a corresponding one of electrical connectors 838 on the opposite face of transducer 820.

The connector footing 850 is similar to the connector footing 650 of the ultrasound transducer 520 shown in FIGS. 26-28 except that the connector footing 850 comprises segments 841-2 in place of segments 641-2. Segments 841-2 are similar to segments 641-2 except that segments 841-2 project into an opposite face of the substrate of transducer array 528. Segments 841-project into the substrate of transducer array 528 same side of transducer array 528 that underlies or supports electrical connectors 138, electrically conductive lines 152 and electrically conductive contact pads 153 and on print circuit board 124). Like segments 641-1, segments 841-2 do not extend completely through the thickness of the substrate. In some implementations, such groups may be formed by a saw and subsequently filled with a more robust material of the connector footing.

The electrical connectors 838, electrically conductive lines 852 and electrically conductive contact pads 853 are similar to connectors 138, conductive lines 152 and contact pads 153, respectively, except that each is formed on an opposite face of transducer 820 as compared to the transducer 520 shown in FIGS. 26-28. As a result, all of the electrical connectors, all of the electrically conductive lines and all of the electrical contact pads associated with printed circuit board 124 are on a single side or face of printed circuit board 124 and a single side or face of transducer array 528. Because such electrical connections occur on a single face of the ultrasound transducer, easier fabrication of transfer 820 may be facilitated.

Although the present disclosure has been described with reference to example implementations, workers skilled in the art will recognize that changes may be made in form and detail without departing from the scope of the claimed subject matter. For example, although different example implementations may have been described as including features providing benefits, it is contemplated that the described features may be interchanged with one another or alternatively be combined with one another in the described example implementations or in other alternative implementations. Because the technology of the present disclosure is relatively complex, not all changes in the technology are foreseeable. The present disclosure described with reference to the example implementations and set forth in the following claims is manifestly intended to be as broad as possible. For example, unless specifically otherwise noted, the claims reciting a single particular element also encompass a plurality of such particular elements. The terms “first”, “second”, “third” and so on in the claims merely distinguish different elements and, unless otherwise stated, are not to be specifically associated with a particular order or particular numbering of elements in the disclosure.

What is claimed is:

1. An ultrasound transducer comprising:
a printed circuit board (PCB);
a transducer array comprising:
a substrate;
an array of Piezo resistive elements supported by the substrate;
at least one connector footing supported by the substrate;
electrically conductive lines connected to the piezoresistive elements; and
an array of connectors electrically connected to the printed circuit board and to the electrically conductive lines, wherein the at least one connector footing supports the array of connectors.

2. The ultrasound transducer of claim 1, wherein the array of connectors comprise electrical contact pads.

3. The ultrasound transducer of claim 1, wherein the at least one connector footing is at least partially received within a recess formed in the substrate.

4. The ultrasound transducer of claim 1, wherein the at least one connector footing extends along an outer edge of the substrate.

5. The ultrasound transducer of claim 1, wherein the array of Piezo resistive elements has an upper surface and wherein the at least one connector footing has a top footing surface coplanar with the upper surface.

6. The ultrasound transducer of claim 1, wherein the connector footing comprises a frame.

7. The ultrasound transducer of claim 1, wherein the substrate is formed from a Piezo resistive material.

8. The ultrasound transducer of claim 5, wherein the array appears in resistive elements are integrally formed as part of a single unitary body with the substrate.

9. The ultrasound transducer of claim 1, wherein the at least one connector footing is formed from a material selected from a group of materials consisting of: glass reinforced epoxy, Borosilicate glass, Alumina nitride, Alumina, Boron Nitride, lead zirconate titanate (PZT) and lead magnesium niobate-lead titanate (PMN-PT).

10. The ultrasound transducer of claim 1, wherein the at least one connector footing has a stiffness of at least 25 GPa.

11. The ultrasound transducer of claim 1, wherein the substrate is etched to form the array of Piezo resistive elements.

12. The ultrasound transducer of claim 1, wherein the array of Piezo resistive elements has a density of at least 5 elements per mm.

13. The ultrasound transducer of claim 1, wherein the connector footing and the piezo-resistive elements are formed from a same material.

14. The ultrasound transducer of claim 1, wherein the substrate is formed from a Piezo resistive material and wherein the connector footing is formed from an electrically insulative material.

15. The ultrasound transducer of claim 1, wherein the connector footing has a thermal conductivity of at least 750 W/mk.

16. A method for forming an ultrasound transducer, the method comprising:
forming an array of Piezo resistive elements on a substrate;
forming at least one connector footing on the substrate;
forming an array of connectors on the at least one connector footing;
electrically connecting the array of Piezo resistive elements to the array of connectors; and
electrically connecting the array of connectors to a printed circuit board.

17. The method of claim 16, wherein the forming of the array of piezo-resistive elements on the substrate comprises removing material from the substrate.

18. The method of claim 17, wherein the material is removed from the substrate by etching.

19. The method of claim 16, wherein forming the at least one connector footing on the substrate comprises:
forming a recess in the substrate; and
positioning the at least one connector footing at least partially within the recess.

20. The method of claim 16, wherein the forming of the array of connectors and the electrically connecting of the array of Piezo resistive elements to the array of connectors comprises:
overlaying an electrically conductive sheet on top of the array of a Piezo resistive elements and on top of the at least one connector footing; and
selectively removing portions of the electrically conductive sheet.
